(19) United States
(12) Patent Application Publication
(10) Pub. No.: US 2011/0164634 A1
(43) Pub. Date: Jul. 7, 2011

(54) SEMICONDUCTOR LASER DEVICE

(75) Inventors: Satsuki KOBAYASHI, Kanagawa (JP); Tsutomu ISHIKAWA, Kanagawa (JP)

(73) Assignee: SUMITOMO ELECTRIC DEVICE INNOVATIONS, INC., Yokohama-shi (JP)

(21) Appl. No.: 13/051,274

(22) Filed: Mar. 18, 2011

Related U.S. Application Data
(63) Continuation of application No. PCT/JP2009/071266, filed on Dec. 22, 2009.

(30) Foreign Application Priority Data
Dec. 26, 2008 (JP) 2008-333510

(51) Int. Cl. H01S 5/024

(52) U.S. Cl. 372/34

(57) ABSTRACT

A semiconductor laser device includes: a semiconductor laser; a carrier that has a carrier side face facing with a longitudinal direction of the semiconductor laser, has a carrier edge area, and has a first bonding area that is the closest to a first end of the semiconductor laser and a second bonding area that is the closet to a second end of the semiconductor laser; a first thermal conduction portion that has a first thermal resistance and couples between the first bonding area and an outer connection terminal; and a second thermal conduction portion that has a second thermal resistance smaller than the first thermal resistance and couples between the second bonding area and an outer connection terminal, wherein the first end side of the semiconductor laser is closer to the carrier side face than the second end side of the semiconductor laser.

### CROSS-REFERENCE TO RELATED APPLICATION

The present application is a continuation of and claims priority to International Patent Application No. PCT/JP2009/071266 filed on Dec. 22, 2009, which claims priority to Japanese Patent Application No. 2008-333510 filed on Dec. 26, 2008, subject matter of these patent documents is incorporated by reference herein in its entirety.

### BACKGROUND

(i) Technical Field

A certain aspect of the embodiments discussed herein is related to a semiconductor laser device.

(ii) Related Art

In a semiconductor laser device, a semiconductor chip and am interconnection metal are provided on a carrier, and a plurality of wirings are coupled to the semiconductor chip in order to provide a current and a voltage to the semiconductor chip. The semiconductor chip is therefore thermally coupled to an outer component through the wirings. In the semiconductor laser device, the carrier is provided on a temperature control device, and the temperature control device controls a temperature of the semiconductor chip.

In the semiconductor laser device, distances between bonding areas of an interconnection metal and the semiconductor laser are hardly different from each other. Therefore, thermal flow amount through each wiring is hardly different from each other, even if outer temperature changes. Therefore, a carrier surface near the semiconductor chip is hardly subjected to the outer temperature. And temperature distribution is kept even.

### SUMMARY

According to an aspect of the present invention, there is provided a semiconductor laser device comprising: a semiconductor laser; a carrier that has a carrier side face facing with a longitudinal direction of the semiconductor laser, has a carrier edge area having a given width from the carrier side face and extending in parallel with the carrier side face, and has a first bonding area that is the closest to a first end of the semiconductor laser on the carrier edge area and a second bonding area that is the closet to a second end of the semiconductor laser on the carrier edge area, the side face being one of sides of the carrier; a first thermal conduction portion that has a first thermal resistance and couples between the first bonding area and an outer connection terminal; and a second thermal conduction portion that has a second thermal resistance smaller than the first thermal resistance and couples between the second bonding area and an outer connection terminal, wherein: the semiconductor laser is mounted on the carrier; and the first end side of the semiconductor laser is closer to the carrier side face than the second end side of the semiconductor laser.

According to an aspect of the present invention, there is provided a semiconductor laser device comprising: a semiconductor laser; a carrier that has a carrier side face facing with a longitudinal direction of the semiconductor laser, has an area extending in parallel with the longitudinal direction of the semiconductor laser, and has a first bonding area that is the closest to a first end of the semiconductor laser on the area and a second bonding area that is the closet to a second end of the semiconductor laser on the area, the side face being one of sides of the carrier; a first thermal conduction portion that couples between the first bonding area and an outer connection terminal; and a second thermal conduction portion that has substantially the same thermal resistance as the first thermal conduction portion and couples between the second bonding area and an outer connection terminal, wherein: the semiconductor laser is mounted on the carrier; and the first end side of the semiconductor laser is closer to the carrier side face than the second end side of the semiconductor laser.

According to an aspect of the present invention, there is provided a semiconductor laser device comprising: a semiconductor laser; a carrier that has a carrier side face facing with a longitudinal direction of the semiconductor laser, has a carrier edge area having a given width from the carrier side face and extending in parallel with the carrier side face, has a first bonding area that is the closest to a first end of the semiconductor laser on the carrier edge area and a second bonding area that is the closet to a second end of the semiconductor laser on the carrier edge area and has a third bonding area that is positioned on the semiconductor laser side compared to the carrier edge area, the side face being one of sides of the carrier; a first thermal conduction portion that has a first thermal resistance and couples between the first bonding area and an outer connection terminal; a second thermal conduction portion that has a second thermal resistance smaller than the first thermal resistance and couples between the second bonding area and an outer connection terminal; and a third thermal conduction portion that couples between the third bonding area and an outer connection terminal, wherein: the semiconductor laser is mounted on the carrier; and the first end side of the semiconductor laser is closer to the carrier side face than the second end side of the semiconductor laser.

### BRIEF DESCRIPTION OF THE DRAWINGS

FIG. 1 illustrates schematic view of a module in which a semiconductor chip is arranged to be inclined;

FIG. 2 illustrates a schematic view of the problem;

FIG. 3A and FIG. 3B illustrate a principle of the invention;

FIG. 4 illustrates a schematic view of a semiconductor laser device in accordance with a first embodiment;

FIG. 5 illustrates a schematic view of a semiconductor laser device in accordance with a second embodiment;

FIG. 6 illustrates a schematic view of a semiconductor laser device in accordance with a third embodiment;

FIG. 7 illustrates a schematic view of a semiconductor laser device in accordance with a fourth embodiment;

FIG. 8 illustrates a schematic view of a semiconductor laser device in accordance with a fifth embodiment;

FIG. 9 illustrates a schematic view of a semiconductor laser device in accordance with a sixth embodiment; and

FIG. 10A and FIG. 10B illustrate an enlarged view of an interconnection metal provided on a carrier.

### DETAILED DESCRIPTION

In a semiconductor laser device in which a semiconductor chip is mounted on a carrier and is inclined with respect to the carrier, distances between the semiconductor chip and bonding areas of an interconnection metal are different from each other. Therefore, thermal flow amount between outside and near the semiconductor chip in a case where the semiconductor chip is closer to the bonding area is different from that in a case where the semiconductor chip is farther from the bonding area, even if the lengths of the wirings are equal to each other. Therefore, the surface temperature of the carrier near the semiconductor chip is distributed disproportionately if the outer temperature changes.

In the semiconductor laser device, it is not possible to equalize the temperature distribution of the carrier surface near the semiconductor chip, because a temperature control device can control only an average temperature of the carrier.

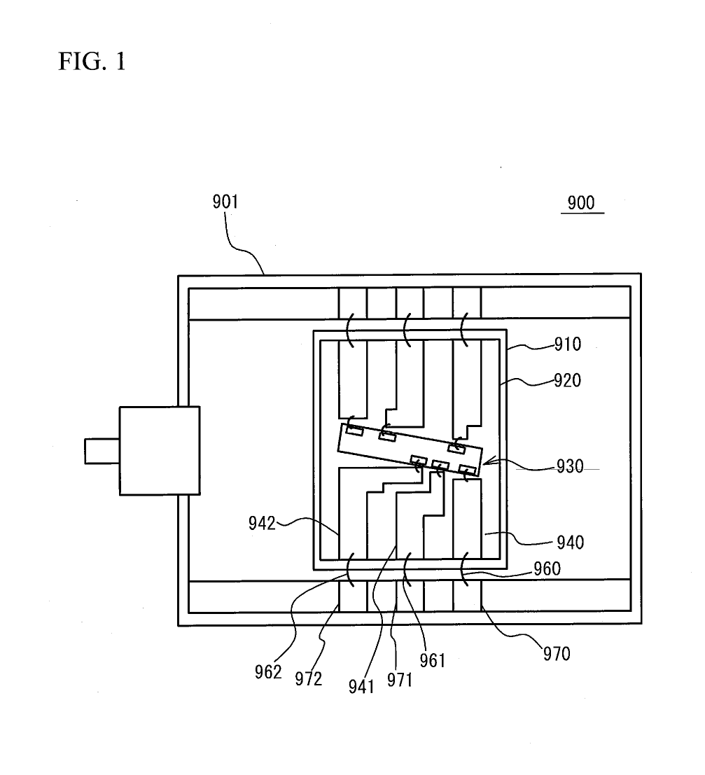

FIG. 1 illustrates a schematic view of a module 900 in which a semiconductor chip is arranged to be inclined. As illustrated in FIG. 1, in the module 900, a carrier 920 is provided on a temperature control device 910 in a package 901. A semiconductor laser 930 is provided on the carrier 920. The carrier 920 has a carrier side face facing with a longitudinal direction of a semiconductor laser 930. A first end of the semiconductor laser 930 is closer to the carrier side face of the carrier 920 than a second end of the semiconductor laser 930. Thus, the semiconductor laser 930 is arranged to be inclined with respect to the carrier 920. The semiconductor laser 930 is coupled to an outer device through wirings 960 to 962 and outer connection terminals 970 to 972 from interconnection metals 940 to 942 on the carrier 920.

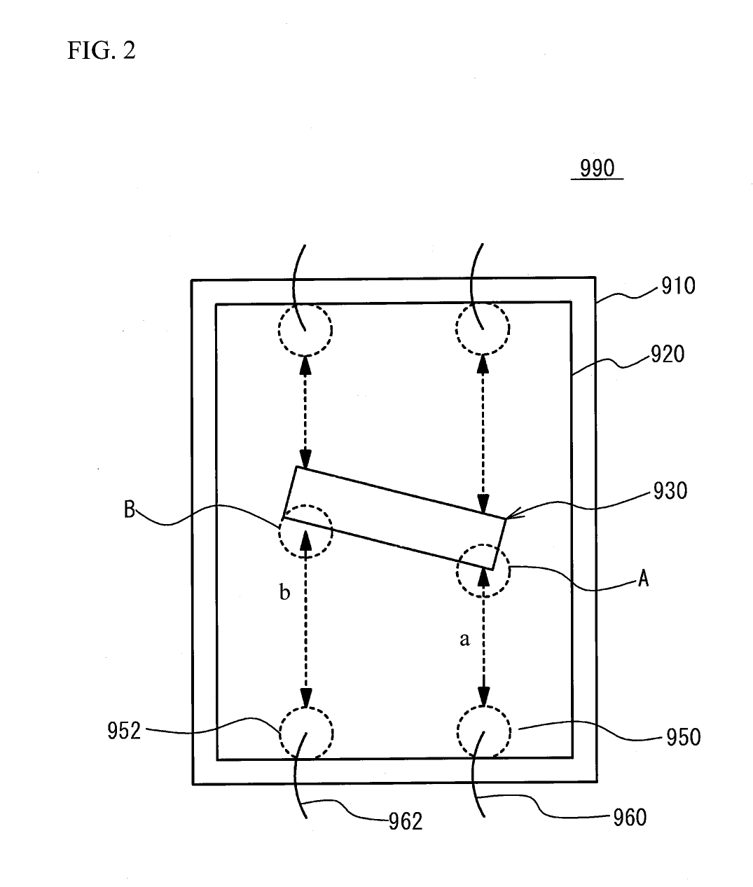

FIG. 2 illustrates a schematic view of the problem. The carrier 920 is mounted on the temperature control device 910 in a module 990. The semiconductor laser 930 is mounted on the carrier 920 and is arranged to be inclined with respect to the carrier 920. The semiconductor laser 930 is coupled to an outer connection terminal through the wirings 960 and 962. The carrier 920 has areas 950 and 952 where a wiring is bonded to a interconnection metal. The areas are hereinafter referred to as a bonding area. The bonding areas 950 and 952 have a bonding pad and so on. The temperature control device 910, the carrier 920, the semiconductor laser 930 and the wirings 960 and 962 are the same as those of FIG. 1.

In the module 990 of FIG. 2, an area A on the first end side of the semiconductor laser 930 has a distance “a” from the bonding area 950, and an area B on the second end side of the semiconductor laser 930 has a distance “b” from the bonding area 952. In FIG. 2, the distance “a” is shorter than the distance “b”. In this case, the area A is more subjected to outer heat than the area B if thermal flow amount toward or from outside through the wirings 960 and 962 is equal to each other. For example, output wavelength may not be stable because temperature difference between the area A and the area B of the semiconductor laser is 0.1 degrees C. or more.

The thermal flow toward or from outside through the wirings 960 and 962 is different from each other, when the distance from the bonding areas 950 and 952 to the outer connection terminal is different from each other, even if the distance between the area A and the bonding area 950 is the same as that between the area B and the bonding area 952. Therefore, one of the areas A and B is subjected to the outer heat more than the other.

A description will be given of a principle of the present invention.

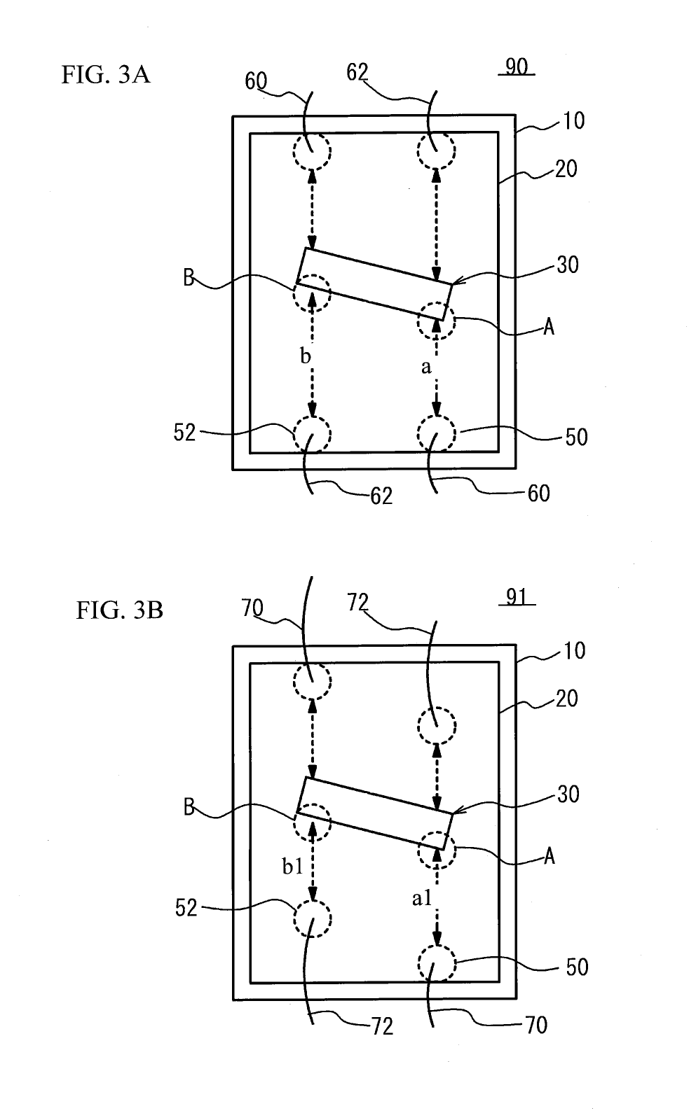

FIG. 3A and FIG. 3B illustrate the principle of the invention. As illustrated in FIG. 3A, a module 90 has a structure in which a carrier 20 is mounted on a temperature control device 10. A semiconductor laser 30 is mounted on the carrier 20 and is arranged to be inclined with respect to the carrier 20. The semiconductor laser 30 is coupled to an outer connection terminal through a bonding area 50 on the carrier 20 and a wiring 60, and is coupled to another outer connection terminal through a bonding area 52 on the carrier 20 and a wiring 62.

In the module 90, the area A on the first end side of the semiconductor laser 30 has a distance “a” from the bonding area 50, and the area B on the second end side of the semiconductor laser 30 has a distance “b” from the bonding area 52. In FIG. 3A, the distance “a” is shorter than the distance “b”. In this case, the area A is more subjected to heat than the area B, if the thermal flow toward or from outside through the wirings 60 and 62 is equal to each other.

And so, thermal flow through the wiring 62 coupled to the bonding area 52 is adjusted to be more than thermal flow through the wiring 60 coupled to the bonding area 50. Alternatively, the thermal flow through the wiring 60 coupled to the bonding area 50 is adjusted to be less than the thermal from through the wiring 62 coupled to the bonding area 52. In this case, temperature distribution of the surface of the carrier 20 near the semiconductor laser 30 caused by the difference of the distances between the semiconductor laser 30 and the bonding areas 50 and 52 may be restrained.

The present invention may be applied to a case where the distances between the semiconductor laser and the bonding areas are equal to each other. As illustrated in FIG. 3B, a module 91 has a structure in which the carrier 20 is mounted on the temperature control device 10. The semiconductor laser 30 is mounted on the carrier 20 and is arranged to be inclined with respect to the carrier 20. The semiconductor laser 30 is coupled to outer connection terminals through the bonding areas 50 and 52 and the wirings 60 and 62.

In the module 91, the area A on the first end side of the semiconductor laser 30 has a distance “a1” from the bonding area 50, and the area B on the second end side of the semiconductor laser 30 has a distance “b1” from the bonding area 52. In FIG. 3B, the distance “a1” and the distance “b1” are set to be substantially equal to each other.

However, in this case, a wiring 72 coupling between the bonding area 52 and an outer connection terminal is longer than a wiring 70 coupling between the bonding area 50 and an outer connection terminal. In this case, thermal resistance of the wiring 70 is smaller than that of the wiring 72. Therefore, the area A is more subjected to heat than the area B. And so, the thermal flow through the wiring 72 coupled to the bonding area 52 is adjusted to be equal to the thermal flow through the wiring 70 coupled to the bonding area 50. Therefore, the temperature distribution of the surface of the carrier 20 near the semiconductor laser 30 is restrained.

A description will be given of embodiments of the present invention.

### First Embodiment

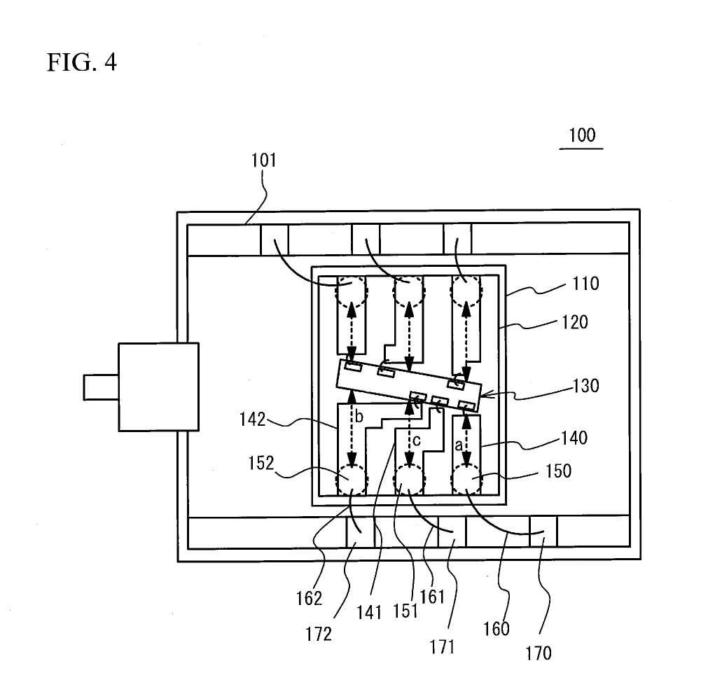

FIG. 4 illustrates a schematic view of a semiconductor laser device 100 in accordance with a first embodiment. As illustrated in FIG. 4, the semiconductor laser device 100 has a structure in which a temperature control device 110 is mounted on a package 101, a carrier 120 is provided on the temperature control device 110, a semiconductor laser 130 is mounted on the carrier 120.

The carrier 120 has a rectangular shape and has a carrier side face facing with a longitudinal direction of the semiconductor laser 130. In FIG. 4, the carrier side face is lower side of the carrier 120. The semiconductor laser 130 is mounted on the carrier 120. The first end side of the semiconductor laser 130 is closer to the carrier side face than the second end side of the semiconductor laser 130. Thus, the semiconductor laser 130 is arranged to be inclined with respect to the carrier 120. In FIG. 4, the first end of the semiconductor laser 130 is right end, and the second end of the semiconductor laser 130 is left end.

The semiconductor laser 130 is coupled to outer connection terminals 170 to 172 through interconnection metals 140 to 142 and wirings 160 to 162. The interconnection metals 140 to 142 respectively have bonding areas 150 to 152 on the opposite side of the semiconductor laser 130. The bonding areas 150 to 152 have a bonding pad and so on.

Here, on the carrier 120, an area having a given width and extending from the carrier side face in parallel with the carrier side face is hereinafter referred to as a carrier edge area. In the embodiment, the bonding areas 150 to 152 are positioned on the carrier edge area. The bonding area 150 is an area of the carrier edge area that is the closest to the first end of the semiconductor laser 130. The bonding area 152 is an area of the carrier edge area that is the closest to the second end of the semiconductor laser 130. The bonding area 151 is positioned between the bonding area 150 and the bonding area 152 on the carrier edge area.

The wirings 160 to 162 respectively couples the bonding areas 150 to 152 and the outer connection terminals 170 to 172. In the embodiment, the wiring 160 is longer than the wiring 162. The wiring 161 is shorter than the wiring 160 and is longer than the wiring 162.

In the embodiment, the distance “a” between the semiconductor laser 130 and the bonding area 150 is shorter than the distance “b” between the semiconductor laser 130 and the bonding area 152. In this case, the first end side of the semiconductor laser 130 is more subjected to thermal flow through a wiring than the second end side. However, thermal resistance of the wiring 160 is larger than that of the wiring 162 because the wiring 160 is longer than the wiring 162. In this case, thermal influence on the first end side of the semiconductor laser 130 from outside is restrained. It is therefore possible to equalize the thermal flow toward or from outside on an area near the semiconductor laser 130. Accordingly, the temperature distribution on the surface of the carrier 120 is restrained.

The temperature distribution on the surface of the carrier 120 is more restrained, because the distance “c” between the semiconductor laser 130 and the bonding area 151 is between the distance “a” and the distance “c”, and the length of the wiring 161 is between the wiring 160 and the wiring 162.

When the distances “a” to “c” are approximately 0.6 mm, 1.0 mm and 1.7 mm, the wiring 160 has a length of approximately 3.3 mm, the wiring 161 has a length of approximately 2.2 mm, the wiring 162 has a length of approximately 1.3 mm, and a cross-section area of the wirings 160 to 162 is approximately 0.00070 mm². The carrier 120 is made of aluminum nitride. The interconnection metals 140, 141 and 142 are made of gold or the like.

An optical component such as a lens may be mounted on an optical axis in front of the semiconductor laser 130 and behind the semiconductor laser 130.

### Second Embodiment

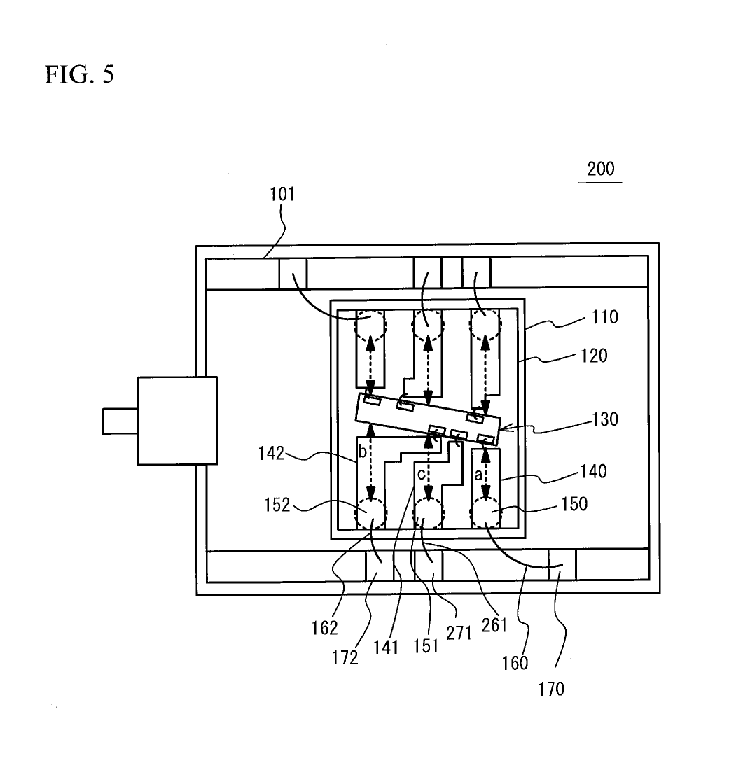

FIG. 5 illustrates a schematic view of a semiconductor laser device 200 in accordance with a second embodiment. The semiconductor laser device 200 is different from the semiconductor laser device 100 in points that a wiring 261 is provided instead of the wiring 161, and an outer connection terminal 271 is provided instead of the outer connection terminal 171. In the embodiment, the outer connection terminal 271 is positioned so that the wiring 261 has the same length as the wiring 162.

In the embodiment, the thermal resistance of the wiring 160 is larger than that of the wiring 162, because the wiring 160 is longer than the wiring 162. It is therefore possible to equalize the thermal flow toward or from outside on the area near the semiconductor laser 130. Accordingly, the temperature distribution of the surface of the carrier 120 is restrained.

### Third Embodiment

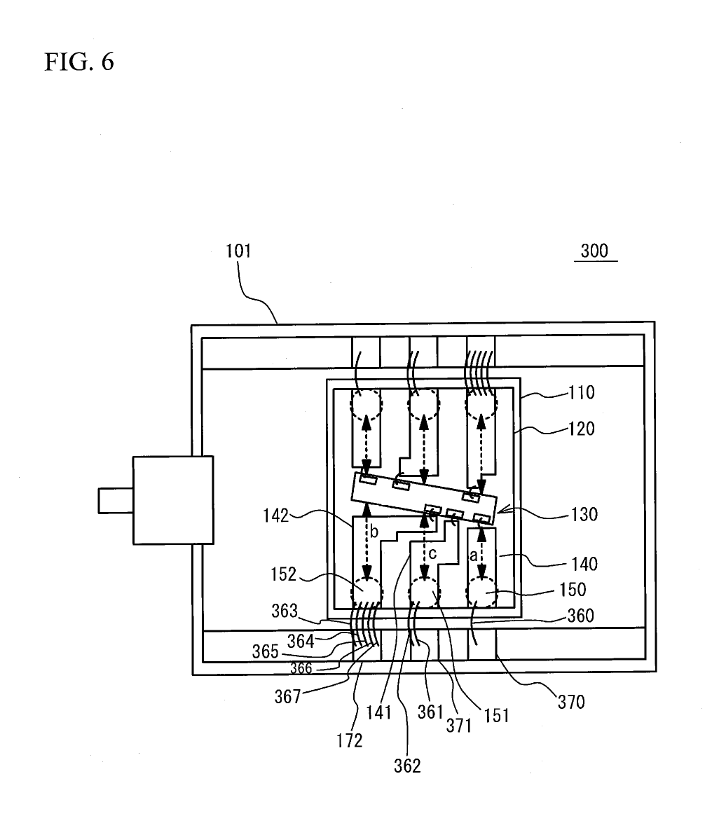

FIG. 6 illustrates a schematic view of a semiconductor laser device 300 in accordance with a third embodiment. As illustrated in FIG. 6, the semiconductor laser device 300 is different from the semiconductor laser device 100 of FIG. 4 in points that a wiring 360 is provided instead of the wiring 160, wirings 361 and 362 are provided instead of the wiring 161, wirings 363 to 367 are provided instead of the wiring 162, and outer connection terminals 370 and 371 are provided instead of the outer connection terminals 170 and 171. Thus, in the embodiment, the bonding area 150 is coupled to the outer connection terminal 370 with a single wiring, the bonding area 151 is coupled to the outer connection terminal 371 with two wirings, and the bonding area 152 is coupled to the outer connection terminal 172 with five wirings.

In this case, the thermal resistance between the bonding area 151 and the outer connection terminal 171 is larger than that between the bonding area 152 and the outer connection terminal 172. The thermal resistance between the bonding area 150 and the outer connection terminal 170 is smaller than that between the bonding area 151 and the outer connection terminal 171. It is therefore possible to equalize the thermal flow toward or from outside on the area near the semiconductor laser 130. Accordingly, the temperature distribution of the surface of the carrier 120 is restrained.

The positions of the outer connection terminals 370, 371 and 172 may be adjusted according to each thermal resistance between the bonding areas and the outer connection terminals. In this case, the temperature distribution of the surface of the carrier 120 is more restrained.

For example, when the distances “a” to “c” are respectively 0.8 mm, 1.8 mm and 1.3 mm approximately, the lengths of the wirings 360 to 367 are approximately 1.9 mm, and the cross-section area of the wirings 360 to 367 is approximately 0.00070 mm².

### Fourth Embodiment

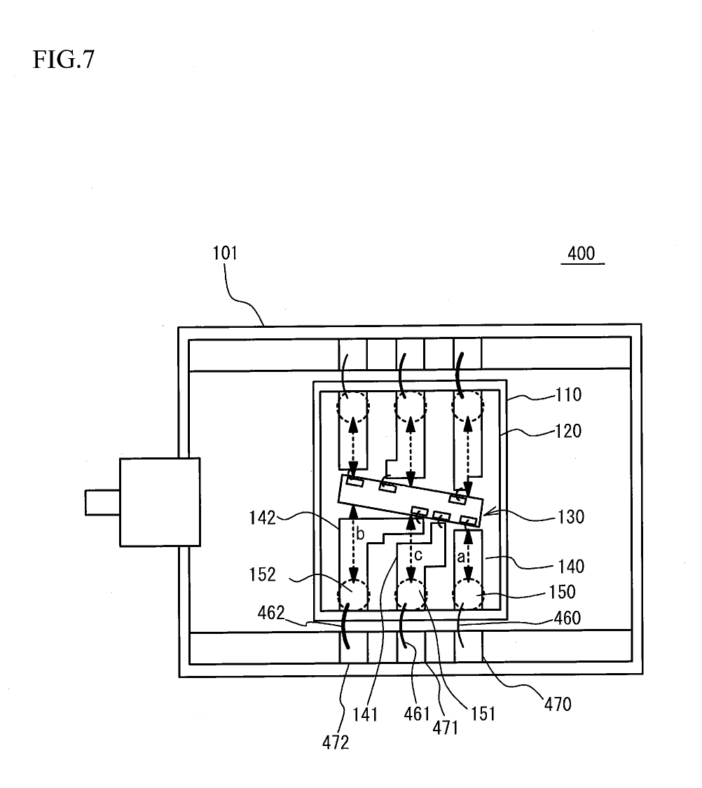

FIG. 7 illustrates a schematic view of a semiconductor laser device 400 in accordance with a fourth embodiment. As illustrated in FIG. 7, the semiconductor laser device 400 is different from the semiconductor laser device 100 in points that wirings 460 to 462 are provided instead of the wirings 160 to 162, and outer connection terminals 470 to 472 are provided instead of the outer connection terminals 170 to 172.

In the embodiment, the cross-section area of the wiring 461 is smaller than that of the wiring 462, and the cross-section area of the wiring 460 is smaller than that of the wiring 461. Thus, the thermal resistance of the wiring 461 is larger than that of the wiring 462, and the thermal resistance of the wiring 460 is larger than that of the wiring 461. It is therefore possible to equalize the thermal flow toward or from outside on the area near the semiconductor laser 130. Accordingly, the temperature distribution of the carrier 120 is restrained.

The positions of the outer connection terminals 470 to 472 may be adjusted according to each thermal resistance between the bonding areas and the outer connection terminals. In this case, the temperature distribution of the surface of the carrier 120 is more restrained.

For example, when the distances “a” to “c” are respectively 0.8 mm, 1.8 mm and 1.3 mm approximately, the cross-section areas of the wirings 460 to 462 are respectively 0.00070 mm², 0.00282 mm², and 0.00125 mm² approximately, and the lengths of the wirings 460 to 462 are approximately 1.9 mm.

### Fifth Embodiment

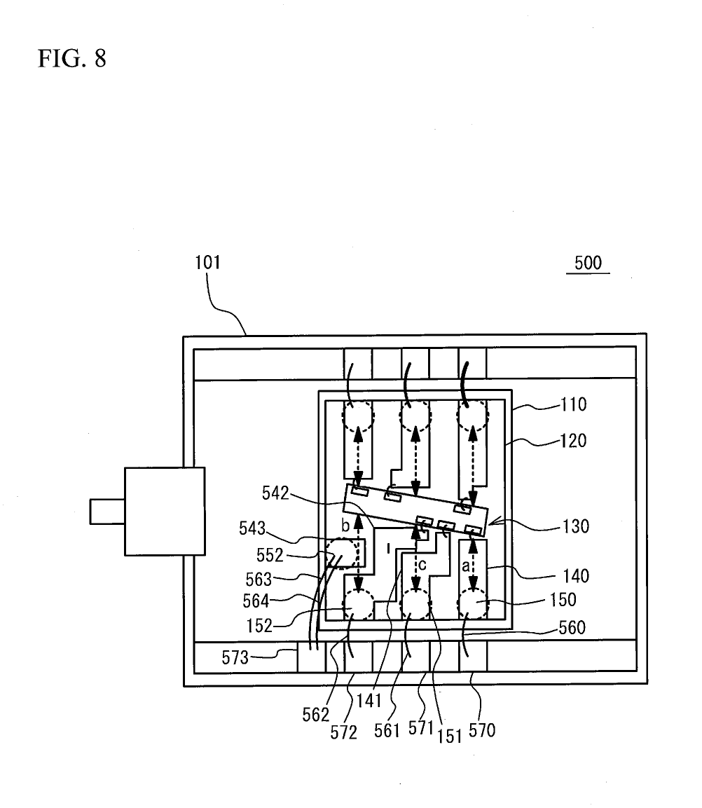

FIG. 8 illustrates a schematic view of a semiconductor laser device 500 in accordance with a fifth embodiment. The semiconductor laser device 500 is different from the semiconductor laser device 100 in points that wirings 560 to 562 are provided instead of the wirings 160 to 162, the outer connection terminals 570 to 572 are provided instead of the outer connection terminals 170 to 172, and bonding areas 552 and 573 and wirings 563 and 564 are further provided.

The bonding area 552 is positioned on the second end side of the semiconductor laser 130 between the carrier edge area and the semiconductor laser 130. That is, the bonding area 552 is positioned on the second end side of the semiconductor laser 130, compared to the bonding areas 150 to 152. The bonding area 573 is positioned away from the carrier 120. For example, the bonding area 573 is positioned on an area where the outer connection terminals 570 to 572 are provided in the package 101. The bonding areas 552 and 573 may not be electrically coupled to the semiconductor laser 130.

In the embodiment, heat flows toward or from outside through the bonding areas 552 and 573 and the wirings 563 and 564. In this case, the area on the second end side of the semiconductor laser 130 is more subjected to the heat of outside. It is therefore possible to equalize the thermal flow toward or from outside on the area near the semiconductor laser 130. Accordingly, the temperature distribution of the surface of the carrier 120 is restrained.

For example, when the distances “a” to “c” are respectively 0.8 mm, 1.8 mm and 1.3 mm approximately, the lengths of the wirings 560 to 564 are respectively 1.9 mm, 1.9 mm, 1.9 mm, 3.2 mm and 3.2 mm approximately, and the cross-section area of the wirings 560 to 564 is approximately 0.00070 mm².

### Sixth Embodiment

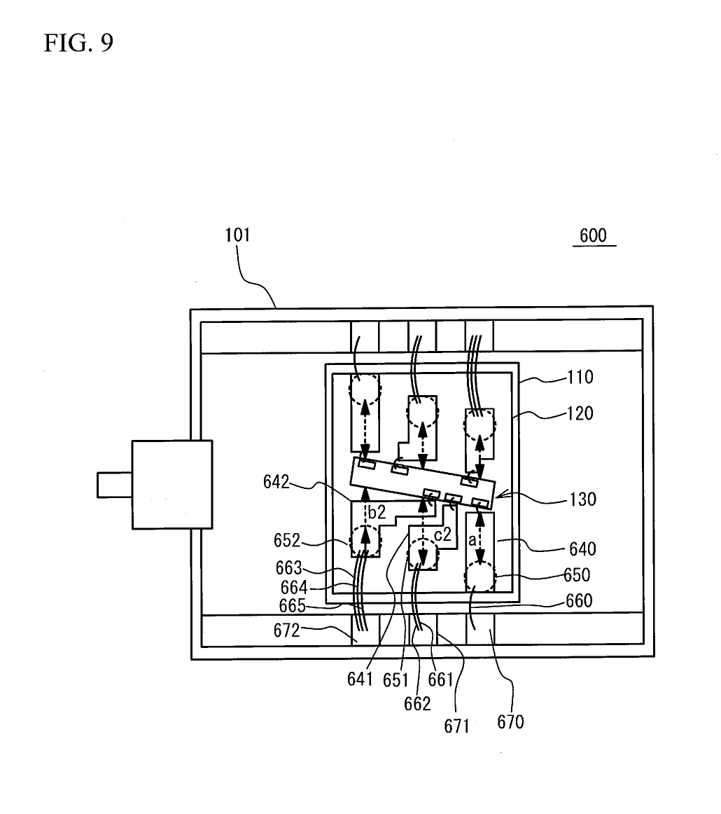

FIG. 9 illustrates a schematic view of a semiconductor laser device 600 in accordance with a sixth embodiment. The semiconductor laser device 600 is different from the semiconductor laser device 100 of FIG. 4 in points that the interconnection metals 640 to 642 are provided instead of the interconnection metals 140 to 142, wirings 660 to 665 are provided instead of the wirings 160 to 162, and outer connection terminals 670 to 672 are provided instead of the outer connection terminals 170 to 172. The interconnection metals 640 to 642 respectively have the bonding areas 650 to 652 on the opposite side of the semiconductor laser 130.

In the semiconductor laser device 600, the bonding area 650 is positioned on the carrier edge area, the bonding area 651 is on the semiconductor laser 130 side compared to the carrier edge area, and the bonding area 652 is on the semiconductor laser 130 side compared to the bonding area 651. In this case, the distance difference between the bonding areas and the semiconductor laser 130 is smaller than the semiconductor laser device 100 of FIG. 4. On the other hand, the distance difference between the bonding areas and the outer connection terminals is larger than the semiconductor laser device 100.

And so, the thermal resistance between the bonding area 651 and the outer connection terminal 671 is adjusted to be larger than that between the bonding area 652 and the outer connection terminal 672, and the thermal resistance between the bonding area 650 and the outer connection terminal 670 is adjusted to be larger than that between the boding area 651 and the outer connection terminal 671. For example, the thermal flow toward or from outside is equalized on the area near the semiconductor laser 130 when each thermal resistance is adjusted according to the number of the wirings as illustrated in FIG. 9. Accordingly, the temperature distribution of the surface of the carrier 120 is restrained.

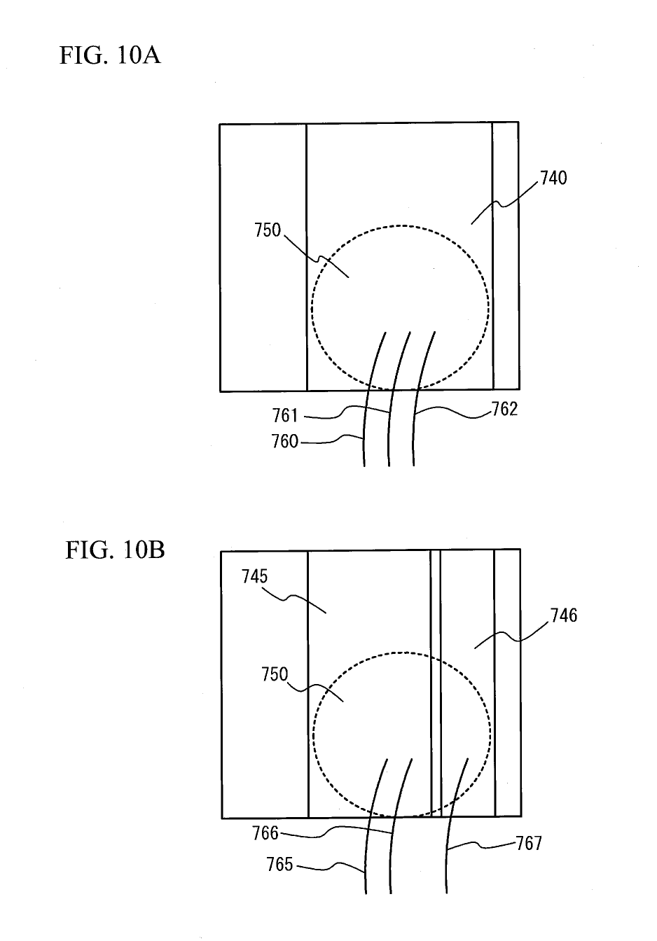

A description will be given of details of the interconnection metal. FIG. 10A and FIG. 10B illustrate an enlarged view of the interconnection metal provided on the carrier. FIG. 10A illustrates the interconnection metal 740, the bonding area 750 and the wirings 760 to 762. FIG. 10B illustrates the interconnection metals 745 and 746, the bonding area 750 and the wirings 765 to 767.

The thermal flow amount through the bonding area hardly depends on a layout (division or connection) of the interconnection metal. The thermal influence from outside of a case where the bonding area 750 is included in the interconnection metal 740 and the wirings 760 to 762 are coupled to the bonding area 750 as illustrated in FIG. 10A is substantially the same as that of a case where the bonding area 750 extends from the interconnection metal 745 to the interconnection metal 746, the wirings 765 and 766 are coupled to the interconnection metal 745, and the wiring 767 is coupled to the interconnection metal 746, if the thermal flow through the bonding area 750 is the same in the cases.

It is preferable that the length, the cross-section area, the material and so on of the wiring coupled to each bonding area are set so that the thermal flow toward or from outside is equalized on the area near the semiconductor laser 130. However, the temperature distribution of the surface of the carrier has only to be restrained.

Conventionally, wavelength was unstable because temperature difference between a first end and a second end of a semiconductor laser was 0.1 degrees C. or more, although the temperature difference may be changed according to outer temperature. In accordance with the embodiment, however, the temperature difference between the first end and the second end of the semiconductor laser was not observed in the same condition.

The present invention is not limited to the specifically described embodiments and variations but other embodiments and variations may be made without departing from the scope of the claimed invention.

What is claimed is:

1. A semiconductor laser device comprising:
a semiconductor laser;
a carrier that has a carrier side face facing with a longitudinal direction of the semiconductor laser, has a carrier edge area having a given width from the carrier side face and extending in parallel with the carrier side face, and has a first bonding area that is the closest to a first end of the semiconductor laser on the carrier edge area and a second bonding area that is the closet to a second end of the semiconductor laser on the carrier edge area, the side face being one of sides of the carrier;
a first thermal conduction portion that has a first thermal resistance and couples between the first bonding area and an outer connection terminal; and
a second thermal conduction portion that has a second thermal resistance smaller than the first thermal resistance and couples between the second bonding area and an outer connection terminal,
wherein:
the semiconductor laser is mounted on the carrier; and
the first end side of the semiconductor laser is closer to the carrier side face than the second end side of the semiconductor laser.

2. The semiconductor laser device as claimed in claim 1, wherein:
the thermal conduction portions are made of a wire; and
the thermal resistance is determined according to the number of the wire.

3. The semiconductor laser device as claimed in claim 1, wherein:
the thermal conduction portions are made of a wire; and
the thermal resistance is determined according to a cross-section area of the wire.

4. The semiconductor laser device as claimed in claim 1, wherein:
the thermal conduction portions are made of a wire; and
the thermal resistance is determined according to a length of the wire.

5. The semiconductor laser as claimed in claim 1, further comprising:
a third bonding area that is provided between the first bonding area and the second bonding area on the carrier edge area; and
a third thermal conduction portion that has a third thermal resistance between the first thermal resistance and the second thermal resistance and couples between the third bonding area and an outer connection terminal.

6. A semiconductor laser device comprising:
a semiconductor laser;
a carrier that has a carrier side face facing with a longitudinal direction of the semiconductor laser, has an area extending in parallel with the longitudinal direction of the semiconductor laser, and has a first bonding area that is the closest to a first end of the semiconductor laser on the area and a second bonding area that is the closet to a second end of the semiconductor laser on the area, the side face being one of sides of the carrier;
a first thermal conduction portion that couples between the first bonding area and an outer connection terminal; and
a second thermal conduction portion that has substantially the same thermal resistance as the first thermal conduction portion and couples between the second bonding area and an outer connection terminal,
wherein:
the semiconductor laser is mounted on the carrier; and
the first end side of the semiconductor laser is closer to the carrier side face than the second end side of the semiconductor laser.

7. The semiconductor laser as claimed in claim 6, further comprising:
a third bonding area that is provided between the first bonding area and the second bonding area on the area extending in parallel with the longitudinal direction of the semiconductor laser; and
a third thermal conduction portion that has a length between the first thermal conduction portion and the second thermal conduction portion and couples between the third bonding area and an outer connection portion.

8. A semiconductor laser device comprising:
a semiconductor laser;
a carrier that has a carrier side face facing with a longitudinal direction of the semiconductor laser, has a carrier edge area having a given width from the carrier side face and extending in parallel with the carrier side face, has a first bonding area that is the closest to a first end of the semiconductor laser on the carrier edge area and a second bonding area that is the closet to a second end of the semiconductor laser on the carrier edge area and has a third bonding area that is positioned on the semiconductor laser side compared to the carrier edge area, the side face being one of sides of the carrier;
a first thermal conduction portion that has a first thermal resistance and couples between the first bonding area and an outer connection terminal;
a second thermal conduction portion that has a second thermal resistance smaller than the first thermal resistance and couples between the second bonding area and an outer connection terminal; and
a third thermal conduction portion that couples between the third bonding area and an outer connection terminal,
wherein:
the semiconductor laser is mounted on the carrier; and
the first end side of the semiconductor laser is closer to the carrier side face than the second end side of the semiconductor laser.
